(19) United States
(12) Patent Application Publication
(10) Pub. No.: US 2012/0080750 A1
(43) Pub. Date: Apr. 5, 2012

(54) SEMICONDUCTOR INTEGRATED CIRCUIT

(75) Inventors: Gyung Tae KIM, Icheon-si (KR); Kang Youl LEE, Icheon-si (KR)

(73) Assignee: HYNIX SEMICONDUCTOR INC., Icheon-si (KR)

(21) Appl. No.: 13/187,704

(22) Filed: Jul. 21, 2011

(30) Foreign Application Priority Data
Sep. 30, 2010 (KR) 10-2010-0095066

(51) Int. Cl. H01L 29/78

(52) U.S. Cl. 257/334; 257/330; 257/E29.262

(57) ABSTRACT

A semiconductor integrated circuit includes: a semiconductor substrate comprising a word line decoder region and a memory cell region; a basic word line formed in the memory cell region in a buried gate type; and an additional word line formed to extend from the word line decoder region across the memory cell region, wherein the additional word line is formed over the basic word line in parallel to the basic word line and is coupled to the basic word line through two or more vias.

### CROSS-REFERENCES TO RELATED APPLICATION

The present application claims priority under 35 U.S.C. §119(a) to Korean application number 10-2010-0095066, filed on Sep. 30, 2010, in the Korean Intellectual Property Office, which is incorporated herein by reference in its entirety as if set forth in full.

### BACKGROUND

1. Technical Field

The present invention relates generally to a semiconductor integrated circuit, and more particularly, to a semiconductor integrated circuit having a buried gate structure.

2. Related Art

As semiconductor apparatuses are highly integrated, a method of forming a buried gate is used for reducing a short channel effect of a MOS transistor. In a semiconductor memory apparatus such as DRAM, since a gate terminal of a transistor serving to select a storage cell is used as a word line, a buried gate is called a buried word line. The buried gate is not formed to protrude on a semiconductor substrate, but is buried within a semiconductor substrate, leading to a reduction of a parasitic static capacitance between a word line and a bit line. Therefore, a coupling effect between the word line and the bit line may decrease.

Meanwhile, a semiconductor memory apparatus includes a plurality of memory cells arranged in a matrix form. The memory cells serve to store data. A memory cell region is divided into unit memory cells by word lines and bit lines crossing without contact. Therefore, the semiconductor memory device can select each of the memory cells by a combination of a corresponding word line and a corresponding bit line, and process data with respect to the selected memory cells. To this end, a circuit such as a word line decoder capable of controlling a plurality of word lines is configured in the memory cell region. In general, the word line decoder is arranged at the sides of the memory cell region. The sides of the memory cell region may indicate edge areas of the semiconductor memory device perpendicular to the word line. If two separate word line decoders are arranged on both sides of the memory cell region, each word line decoder may control odd word lines and even word lines, respectively.

To reduce a chip size of a semiconductor memory apparatus, an area of a memory cell region per a word line decoder is gradually increasing. This is because a total necessary region of a word line decoder region may be reduced by allocating larger area to the word line decoder. Therefore, a length of a word line formed across a memory cell region is increasing and the resistance of the word line is increasing with the increase in the length of the word line. The increase in the resistance of the word line means an increase in a time difference when signals are transmitted to start and end points of the word line. Accordingly, tRCD (RAS to CAS Delay, a time from an active command to a read command) characteristics, which is a timing characteristic of a semiconductor memory apparatus such as a DRAM, and tRP (a time from a disabling of an active operation to a starting of a precharge operation) characteristics may deteriorate.

FIGS. 1A and 1B are a cross-sectional view and a plan view respectively illustrating a known semiconductor integrated circuit, and the semiconductor integrated circuit illustrated in FIGS. 1A and 1B has a buried gate structure.

Referring to FIGS. 1A and 1B, a semiconductor substrate Sub is divided into a first word line decoder region SWL_Even, a memory cell region Memory_Cell, and a second word line decoder region SWL_Odd. The first word line decoder region SWL_Even and the second word line decoder region SWL_Odd are regions for word line decoder circuits that receive address signals of a semiconductor apparatus and enable corresponding word lines, and the memory cell region Memory_Cell is a region for storage cells and transistors that are turned on by the word lines. The first word line decoder region SWL_Even and the second word line decoder region SWL_Odd are regions for word line decoder circuits that control even word lines and odd word lines.

In the memory cell region Memory_Cell, the word line WL is illustrated in a buried gate type in which it is buried within the semiconductor substrate Sub. The word line WL is generally formed of polysilicon. In the memory cell region Memory_Cell, a bit line BL is formed over the word line WL such that the bit line BL and the word line WL cross. In the semiconductor memory apparatus such as a DRAM, the bit line BL is a line on which charge sharing is performed with the storage cell and an amplification operation is performed by a sense amplifier. In addition, the bit line BL is a line through which data is inputted/outputted to/from the storage cell.

In the first word line decoder region SWL_Even, a signal transfer line PL is formed over the bit line BL. In general, the signal transfer line PL is formed of a first metal in a fabrication process of a semiconductor apparatus.

The signal transfer line PL and the word line WL are electrically connected together through a via VIA formed therebetween. Therefore, the output signal of the word line decoder circuit is transferred to the word line through the signal transfer line PL.

As described above, the length of the word line WL is increasing in order to reduce the chip size of the semiconductor memory apparatus. In addition, the number of bit lines BL formed over the word lines WL is increasing. Therefore, the delay time from the point of time when the signal is transferred from the word line decoder to the start point aa of the word line through the signal transfer line PL and the via VIA to the point of time when the signal is transferred to the end point bb of the word line may increase. Also, the tRCD and tRP characteristics may deteriorate due to the delay time, and thus operation speed of the semiconductor memory apparatus may decrease.

### SUMMARY

In one embodiment of the present invention, a semiconductor integrated circuit includes: a semiconductor substrate comprising a word line decoder region and a memory cell region; a basic word line in the memory cell region in a buried gate type; and an additional word line formed to extend from the word line decoder region across the memory cell region, wherein the additional word line is formed over the basic word line in parallel to the basic word line and is coupled to the basic word line through at least a first via and a second via.

In another embodiment of the present invention, a semiconductor integrated circuit includes: a semiconductor substrate comprising a first word line decoder region, a second word line decoder region, and a memory cell region; a basic word line formed in the memory cell region in a buried gate type; a first additional word line formed and extending from the first word line decoder region across the memory cell region; and a second additional word line formed of the metal and alternately formed on the same layer as the first additional word line, wherein the second additional word line extends from the second word line decoder region across the memory cell region, wherein the first additional word line and the second additional word line are formed over the basic word line in parallel to the basic word line and are coupled to one basic word line through at least a first via and a second via.

In another embodiment of the present invention, a semiconductor integrated circuit includes: a memory cell region; a word line decoder region provided around the memory cell region; a plurality of basic word lines arranged on the memory cell region in a buried gate type; and a plurality of additional word lines formed of a metal, electrically connected to the plurality of basic word lines, and arranged on the memory cell region.

### BRIEF DESCRIPTION OF THE DRAWINGS

Features, aspects, and embodiments are described in conjunction with the attached drawings, in which:

FIGS. 1A and 1B are a cross-sectional view and a plan view respectively illustrating a known semiconductor integrated circuit;

FIGS. 2A and 2B are a cross-sectional view and a plan view respectively illustrating a semiconductor integrated circuit according to one embodiment of the present invention;

FIGS. 3A and 3B are a cross-sectional view and a plan view respectively illustrating a semiconductor integrated circuit according to another embodiment of the present invention; and

FIGS. 4A and 4B are a cross-sectional view and a plan view respectively illustrating a semiconductor integrated circuit according to another embodiment of the present invention.

### DETAILED DESCRIPTION

Hereinafter, a semiconductor integrated circuit according to the present invention will be described below with reference to the accompanying drawings through exemplary embodiments.

A semiconductor integrated circuit according to an embodiment of the present invention can reduce resistances of word lines, and thus improving timing characteristics related to word lines WL, such as tRCD and tRP.

The semiconductor integrated circuit according to an embodiment of the present invention forms an additional word line assisting a word line WL by using a first metal layer, and thus reduces a total resistance of the word line. In addition, the additional word line may be formed to extend from the signal transfer line PL.

According to an embodiment of the present invention, the total resistance of the word line may decrease and the timing characteristics such as tRCD and tRP may be improved, achieving a higher speed operation of the semiconductor apparatus. In addition, according to an embodiment of the present invention, the memory cell region Memory_Cell allocated to the word line decoder regions SWL_Even and SWL_Odd may be set to be wider. Accordingly, since the total word line decoder region decreases, the chip size of the semiconductor memory apparatus may decrease.

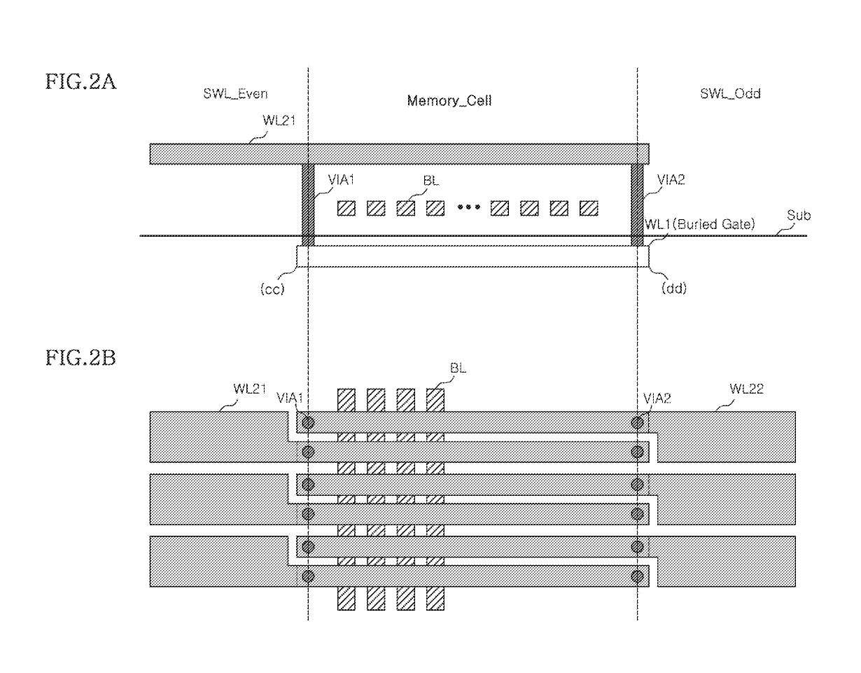

FIGS. 2A and 2B are a cross-sectional view and a plan view respectively illustrating a semiconductor integrated circuit according to an embodiment of the present invention

The semiconductor integrated circuit includes a semiconductor substrate Sub that is divided into a first word line decoder region SWL_Even, a second word line decoder region SWL_Odd, and a memory cell region Memory_Cell.

In the memory cell region Memory_Cell of the semiconductor substrate Sub, a word line is formed in a buried gate type. The word line is referred to as a basic word line WL1.

A bit lines BL is formed over the basic word line WL1, and the bit line BL and the basic word line WL1 cross.

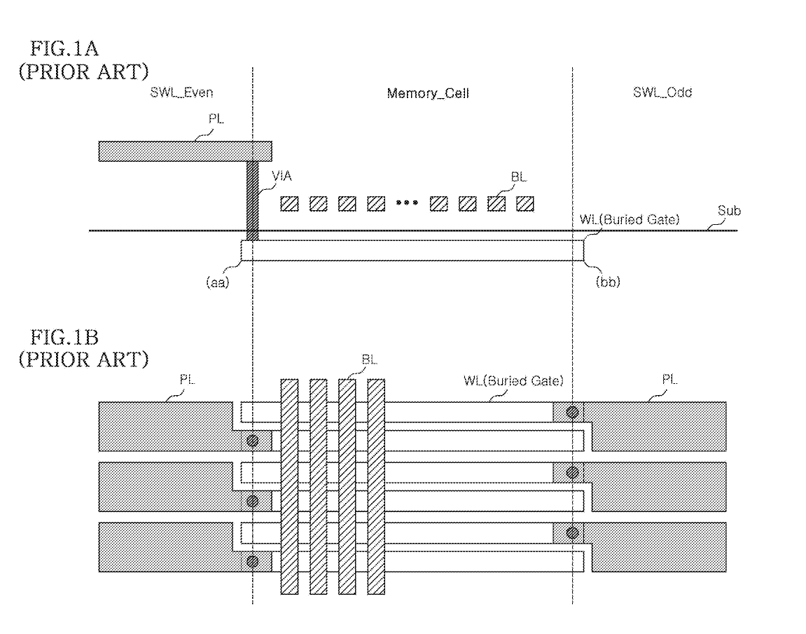

A first additional word line WL21 is formed to extend from the first word line decoder region SWL_Even across the memory cell region Memory_Cell, and a second additional word line WL22 is formed on the same layer as the first additional word line WL21 such that it extends from the second word line decoder region SWL_Odd across the memory cell region Memory_Cell. As illustrated in FIG. 2B, the first additional word line WL21 and the second additional word line WL22 are alternately arranged. The plan view of FIG. 2B illustrates both of the first additional word line WL21, which is formed to extend from the first word line decoder region SWL_Even across the memory cell region Memory_Cell, and the second additional word line WL22, which is formed to extend from the second word line decoder region SWL_Odd across the memory cell region Memory_Cell. The cross-sectional view of FIG. 2A illustrates the first additional word line WL21, which is formed to extend from the first word line decoder region SWL_Even across the memory cell region Memory_Cell. The first and second additional word lines WL21 and WL22 are formed over the bit line BL, for example, in parallel to the basic word line WL1. In addition, the first and second additional word lines WL21 and WL22 are coupled to the basic word line WL1 through two vias VIA1 and VIA2. The first via VIA1 of the two vias VIA1 and VIA2 may be formed in an interface area between the first word line decoder region SWL_Even and the memory cell region Memory_Cell, and the second via VIA2 may be formed in an interface area between the memory cell region Memory_Cell and the second word line decoder region SWL_Odd. The first and second additional word lines WL21 and WL22 may perform the function of the signal transfer line PL illustrated in FIGS. 1A and 1B. For example, the first and second additional word lines WL21 and WL22 may receive signals from the word line decoder circuit and transfer the received signals to the basic word line WL1. As illustrated in FIGS. 2A and 2B, the first and second additional word lines WL21 and WL22 may be formed in such a manner that the signal transfer line PL formed in the first or second word line decoder region SWL_Even or SWL_Odd of FIGS. 1A and 1B extends to the memory cell region Memory_Cell. The first and second additional word lines WL21 and WL22 may be formed in such a manner that the first and second additional word lines WL21 and WL22 are formed as separate lines, instead of extending the signal transfer line PL, and are coupled to the signal transfer line PL. However, as illustrated in FIGS. 2A and 2B, if the first and second additional word lines WL21 and WL22 are formed by extending the signal transfer line PL, no additional connection and via are needed. Thus, advantages can be obtained in terms of a line resistance. In particular, in the fabrication process of the semiconductor integrated circuit, the first and second additional word lines WL21 and WL22 can be formed at the same time during the process of forming the signal transfer line PL. In addition, as illustrated in FIG. 2, if the first and second additional word lines WL21 and WL22 are formed by extending the signal transfer line PL, no additional mask for forming the first and second additional word lines WL21 and WL22 is required. Thus, the first and second additional word lines WL21 and WL22 can be easily formed.

The semiconductor integrated circuit illustrated in FIGS. 2A and 2B may have advantages over the semiconductor integrated circuit illustrated in FIGS. 1A and 1B in terms of the resistance of the word line. Since the first and second additional word lines WL21 and WL22 are coupled in parallel to the basic word line WL1, the total resistance of the basic word line WL1 and the first additional word line WL21 illustrated in FIGS. 2A and 2B is smaller than the total resistance of the word line WL and the signal transfer line PL illustrated in FIGS. 1A and 1B. Accordingly, the delay time from the point of time when the output signal of the word line decoder circuit arrives at the start point cc of the basic word line WL1 illustrated in FIG. 2A to the point of time when the output signal of the word line decoder circuit arrives at the end point dd of the basic word line WL1 can be shorter than the delay time to the point of time when the output signal of the word line decoder circuit arrives at the start point aa of the word line WL illustrated in FIG. 1A to the point of time when the output signal arrives at the end point bb of the word line WL. As simulation results of the semiconductor integrated circuit being currently produced, it can be seen that the delay time decreases from 4 ns to 2.5 ns.

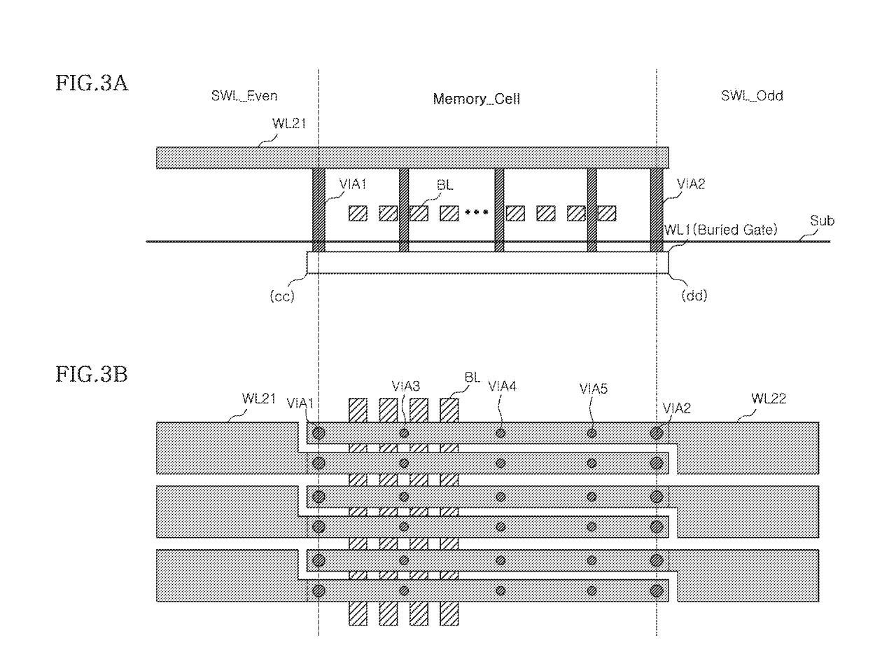

FIGS. 3A and 3B are a cross-sectional view and a plan view respectively illustrating a semiconductor integrated circuit according to an embodiment of the present invention. The semiconductor integrated circuit illustrated in FIGS. 3A and 3B is configured to include more vias than the semiconductor integrated circuit illustrated in FIGS. 2A and 2B. In the semiconductor integrated circuit illustrated in FIGS. 3A and 3B, the basic word line WL1 and the first or second additional word line WL21 or WL22 are coupled through five vias VIA1 through VIA5. It should be noted that the number of vias in FIGS. 2A and 2B is just an example, and thus the number of the vias is not limited thereto. As illustrated in FIGS. 3A and 3B, if the basic word line WL1 or the first or second additional word line WL21 or WL22 are coupled through more vias, the delay time from the point of time when the output signal of the word line decoder circuit arrives at the start point cc of the basic word line WL1 to the point of time when the output signal of the word line decoder circuit arrives at the end point dd of the basic word line WL1 may become shorter than that in the semiconductor integrated circuit illustrated in FIGS. 2A and 2B. As illustrated in FIGS. 3A and 3B, the third through fifth vias VIA3 through VIA5 may be formed between the adjacent bit lines BL formed in the memory cell region Memory_Cell.

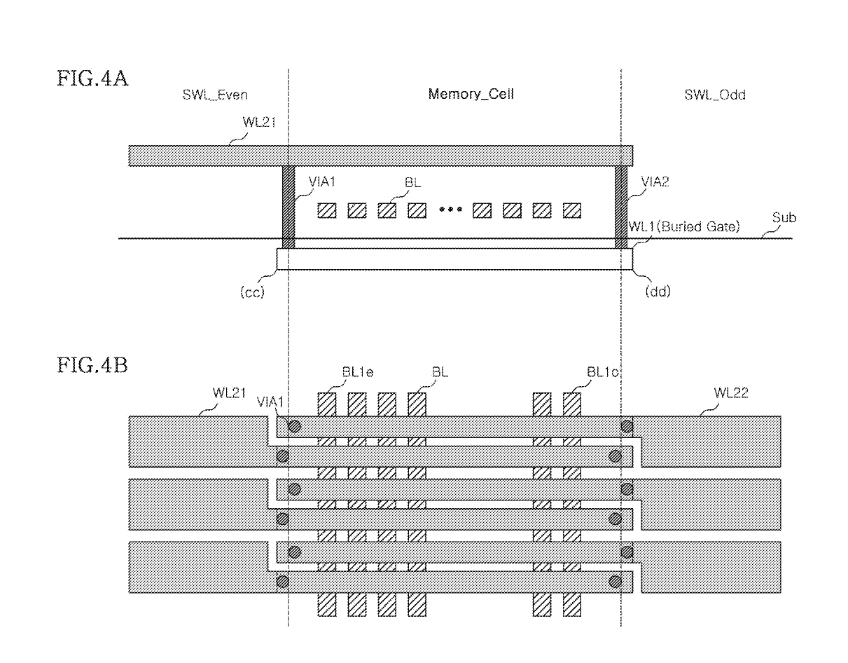

FIGS. 4A and 4B are a cross-sectional view and a plan view respectively illustrating a semiconductor integrated circuit according to an embodiment of the present invention. In the semiconductor integrated circuit illustrated in FIGS. 4A and 4B, the arrangement of the first via VIA1 and the second via VIA2 is modified, as compared to the semiconductor integrated circuit illustrated in FIGS. 2A and 2B. In the fabrication process of the semiconductor integrated circuit, forming the vias adjacently may cause a contact failure due to exposure failure. A process minimum interval between adjacent patterns may vary according to semiconductor fabrication equipment. In addition, the process minimum interval may vary according to the degree of high integration related to forming the patterns in the semiconductor integrated circuit. Accordingly, to reduce a probability of occurrence of defects, a distance between the adjacent vias may be set to be larger than the process minimum interval. In FIGS. 4A and 4B, the first via VIA1 and the second via VIA2 are arranged in a zigzag form, that is, alternately arranged in two parallel lines (not shown) in order to secure the distance between the adjacent vias. Accordingly, the distance between the adjacent vias of the semiconductor integrated circuit illustrated in FIGS. 4A and 4B may be longer than the distance between the adjacent vias of the semiconductor integrated circuit illustrated in FIGS. 2A and 2B. The first via VIA1 is formed between the first word line decoder region SWL_Even and the first bit line BL1e adjacent thereto. To secure at least the process minimum interval, the first via VIA1 may be arranged in a zigzag form. According to an example, if one of two adjacent first vias VIA1 is formed in the first word line decoder region SWL_Even, the other of the two adjacent first vias VIA1 is formed in the memory cell region Memory_Cell. The second via VIA2 is also formed between the second word line decoder region SWL_Odd and the first bit line BL1o adjacent thereto. To secure at least the process minimum interval, the second via VIA2 may be arranged in a zigzag form. According to an example, if one of two adjacent second vias VIA2 is formed in the second word line decoder region SWL_Odd, the other of the two adjacent second vias VIA2 is formed in the memory cell region Memory_Cell.

While certain embodiments have been described above, it will be understood to those skilled in the art that the embodiments described are by way of example only. Accordingly, the semiconductor integrated circuit described herein should not be limited based on the described embodiments. Rather, the semiconductor integrated circuit described herein should only be limited in light of the claims that follow when taken in conjunction with the above description and accompanying drawings.

What is claimed is:

1. A semiconductor integrated circuit comprising:
a semiconductor substrate comprising a word line decoder region and a memory cell region;
a basic word line formed in the memory cell region in a buried gate type; and
an additional word line formed to extend from the word line decoder region across the memory cell region, wherein the additional word line is formed over the basic word line in parallel to the basic word line and is coupled to the basic word line through at least a first via and a second via.

2. The semiconductor integrated circuit according to claim 1, wherein the first via coupling the basic word line to the additional word line is formed in an interface area between the word line decoder region and the memory cell region, and the second via coupling the basic word line to the additional word line is formed in an interface area between the word line decoder region and the memory cell region.

3. The semiconductor integrated circuit according to claim 2, further comprising:
one or more of another via formed between the first via and the second via for coupling the basic word line to the additional word line.

4. The semiconductor integrated circuit according to claim 1, wherein the first vias are arranged in a zigzag form.

5. The semiconductor integrated circuit according to claim 1, wherein the second vias are arranged in a zigzag form.

6. The semiconductor integrated circuit according to claim 1, further comprising:
a bit line formed in the memory cell region between the basic word line layer and the additional word line layer.

7. The semiconductor integrated circuit according to claim 6, further comprising:
a transistor using the basic word line as a gate terminal and coupled to the bit line.

8. The semiconductor integrated circuit according to claim 7, wherein the basic word line and the additional word line are coupled through an additional via between the first via and the second via, and the additional via is formed between two adjacent bit lines.

9. The semiconductor integrated circuit according to claim 1, wherein the basic word line is formed of polysilicon.

10. The semiconductor integrated circuit according to claim 1, wherein the word line decoder region comprises a metal interconnection, and the additional word line extends from the metal interconnection.

11. A semiconductor integrated circuit comprising:
a semiconductor substrate comprising a first word line decoder region, a second word line decoder region, and a memory cell region;
a basic word line formed in the memory cell region in a buried gate type;
a first additional word line extending from the first word line decoder region across the memory cell region; and
a second additional word line formed of the metal and alternately formed on the same layer as the first additional word line, wherein the second additional word line extends from the second word line decoder region across the memory cell region,
wherein the first additional word line and the second additional word line are formed over the basic word line in parallel to the basic word line and are coupled to one basic word line through at least a first via and a second via.

12. The semiconductor integrated circuit according to claim 11, wherein the first via is formed in an interface area between the word line decoder region and the memory cell region, and the second via is formed in an interface area between the second word line decoder region and the memory cell region.

13. The semiconductor integrated circuit according to claim 12, further comprising:
one or more of another via formed between the first via and the second via for coupling the basic word line to the additional word line.

14. The semiconductor integrated circuit according to claim 11, wherein the first vias are arranged in a zigzag form.

15. The semiconductor integrated circuit according to claim 11, wherein the second vias are arranged in a zigzag form.

16. The semiconductor integrated circuit according to claim 11, further comprising:
a bit line formed in the memory cell region between the basic word line layer and the first and second word line layers.

17. The semiconductor integrated circuit according to claim 16, further comprising:
a transistor using the basic word line as a gate terminal and coupled to the bit line.

18. The semiconductor integrated circuit according to claim 17, wherein the basic word line and the first and second additional word lines are coupled through an additional via between the first via and the second via, and the additional via is formed between two adjacent bit lines.

19. The semiconductor integrated circuit according to claim 11, wherein the basic word line is formed of polysilicon.

20. A semiconductor integrated circuit comprising:
a memory cell region;
a word line decoder region provided around the memory cell region;
a plurality of basic word lines arranged on the memory cell region in a buried gate type; and
a plurality of additional word lines formed of a metal, electrically connected to the plurality of basic word lines, and arranged on the memory cell region.

21. The semiconductor integrated circuit according to claim 20, wherein the word line decoder region comprises a plurality of signal transfer lines electrically coupled to the plurality of basic word lines, respectively.

22. The semiconductor integrated circuit according to claim 21, wherein each of the plurality of additional word lines extends from the plurality of signal transfer lines and is electrically coupled to the basic word line through two or more vias.

23. The semiconductor integrated circuit according to claim 22, wherein the first via of the two vias is located at a connection position of the signal transfer line and the additional word line.

24. The semiconductor integrated circuit according to claim 23, wherein the second via of the two vias is located at the basic word line and an opposite end portion of the signal transfer line of the additional word line.

25. The semiconductor integrated circuit according to claim 24, wherein the first via is arranged in a zigzag form to secure a process minimum interval with the adjacent first via.

26. The semiconductor integrated circuit according to claim 24, wherein the second via is arranged in a zigzag form to secure a process minimum interval with the adjacent first via.

27. The semiconductor integrated circuit according to claim 20, wherein the basic word line is formed of polysilicon.
